(19) United States
(12) Patent Application Publication
(10) Pub. No.: US 2021/0343920 A1
(43) Pub. Date: Nov. 4, 2021

(54) THERMOELECTRIC DEVICE

(71) Applicant: Sumitomo Chemical Company Limited, Tokyo (JP)

(72) Inventors: Thomas Fletcher, Godmanchester (GB); Simon King, Godmanchester (GB); Wichita Koomar-Pokhot, Bramptom (GB)

(73) Assignee: Sumitomo Chemical Company Limited, Tokyo (GB)

(21) Appl. No.: 17/280,516

(22) PCT Filed: Sep. 25, 2019
(86) PCT No.: PCT/GB2019/052701

§ 371 Date: Mar. 26, 2021

(30) Foreign Application Priority Data
Sep. 28, 2018 (GB) 1815883.2
Nov. 8, 2018 (GB) 1818208.9

(51) Int. Cl. H01L 35/16; H01L 35/34

(52) U.S. Cl. CPC H01L 35/16; H01L 35/34

(57) ABSTRACT

A double layered, flexible thermoelectric generator with direct bonded, double layers of active materials that are directly bonded by heat curing, not soldered nor attached/bonded by an adhesive layer. The thermoelectric device is made from a first substrate and a second substrate, each including an n-type and p-type thermoelectric legs. The first and the second substrate are brought together so that the n-type and p-type thermoelectric legs of the first substrate come into direct contact with, respectively, the n-type and the p-type thermoelectric legs of the second substrate. Each thermoelectric leg may be disposed in a well formed in an insulating layer disposed over contact electrodes supported on the first and second substrate. Each thermoelectric leg may contain a particulate semiconductor and a binder, e.g. a polymer binder. The pairs of legs are bonded together by heat curing.

### BACKGROUND

Embodiments of the present disclosure relate to a flexible thermoelectric device, for example a flexible thermoelectric generator (TEG).

A thermoelectric device can be used to generate electrical power or as a heating/cooling device. A thermoelectric device includes at least one thermoelectric couple. A thermoelectric couple includes an n-type thermoelectric leg electrically coupled by a contact to a p-type thermoelectric leg. The thermoelectric device may comprise a plurality of electrically connected thermoelectric couples, forming a plurality of alternating n-type thermoelectric legs and p-type thermoelectric legs electrically connected across each leg in series.

In use, a temperature difference may be applied across the thermoelectric device in a second direction that is different to and/or orthogonal to the first direction. The temperature difference is applied across a contact-thermoelectric element boundary. In response to the temperature difference, a voltage is generated by the thermoelectric elements. This voltage can be used to drive a current through the thermoelectric device. Alternatively, a current may be driven through the thermoelectric device to produce a temperature difference across the device which can be used to cool or heat a thermal load.

Thermal and electrical resistance between the contacts and the thermoelectric element affects the power efficiency of the thermoelectric device.

U.S. Pat. No. 7,999,172 describes a flexible thermoelectric device and a manufacturing method thereof.

US 2016/0163948 discloses a bonding of a thermoelectric material leg to a header or an electrical connector.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

Embodiments of the present disclosure provide a method of forming a thermoelectric device in which first and second substrates each carrying n-type and p-type thermoelectric legs are brought together such that the n-type and p-type thermoelectric legs disposed over the first substrate come into direct contact with, respectively, the n-type and the p-type thermoelectric legs disposed over the second substrate.

The first substrate may support a first electrical contact having a first n-type thermoelectric leg disposed thereover and a second electrical contact having a first p-type thermoelectric leg disposed thereover.

The second substrate may support a third electrical contact having a second n-type thermoelectric leg and a second p-type thermoelectric leg disposed thereover.

The present inventors have found that forming a “double” thermoelectric device by this approach provides a simple approach for increasing the thickness of the thermoelectric legs of a thermoelectric device, which may allow for a high thermovoltage as compared to a device formed from the thermoelectric legs of only one of the first and second substrates. By “thickness” of a thermoelectric leg as used herein is meant the distance that the thermoelectric leg extends across between the electrical contacts of the thermoelectric leg.

In some embodiments, the n-type thermoelectric leg and/or the p-type thermoelectric leg contains a semiconducting particles dispersed in a binder.

In some embodiments, the n-type semiconducting particles contain an alloy of bismuth, and tellurium or selenium.

In some embodiments the p-type semiconducting particles contain an alloy of bismuth, tellurium and antimony.

In some embodiments the binder of the n-type and/or p-type thermoelectric leg is a thermosetting polymer.

In some embodiments the binder of the n-type and/or p-type thermoelectric leg is a heat-curable epoxy.

In some embodiments, heat is applied to the thermoelectric legs upon their direct contact.

In some embodiments, at least one of the p-type thermoelectric leg carried by the first substrate, the n-type thermoelectric leg carried by the first substrate, the p-type thermoelectric leg carried by the second substrate and the n-type thermoelectric leg carried by the second substrate is formed by printing an ink onto the electrical contact associated with the thermoelectric leg.

In some embodiments, a patterned insulating structure is supported by the first substrate and/or the second substrate, the insulating structure having apertures exposing electrical contacts, wherein an ink for forming the n-type thermoelectric legs and an ink for forming the p-type thermoelectric legs is printed into the apertures.

In some embodiments, an adhesive is applied to a perimeter of the device between the first and second electrodes in between the first and second substrates.

In some embodiments, the thermoelectric device is flexible.

In some embodiments, at least one of the first and second substrates has a metal foil layer and an insulating layer.

In some embodiments, the thermoelectric device contains a plurality of electrically connected thermoelectric couples, the plurality of electrically connected thermoelectric couples being formed by bringing a plurality of the first n-type thermoelectric legs and a plurality of the first p-type thermoelectric legs into direct contact with, respectively, a plurality of the second n-type thermoelectric legs and a plurality of the second p-type thermoelectric legs.

In some embodiments there is provided a thermoelectric device obtainable by a method as described herein.

### BRIEF DESCRIPTION OF DRAWINGS

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1A provides a schematic side view of first and second substrate for forming a thermoelectric device according to some embodiments, each substrate carrying an electrical contact and an insulating structure;

FIG. 1B provides a schematic side view of the substrates of FIG. 1A following formation of n-type and p-type thermoelectric legs in wells defined in the insulating structures;

FIG. 1B provides a schematic side view of a thermoelectric device according to some embodiments formed by bringing the substrates of FIG. 1B together;

FIG. 2 provides a schematic side view of a first substrate wherein an upper surface of thermoelectric legs disposed over the first substrate extends beyond an upper surface of an insulating structure of the first substrate;

FIG. 3 provides a schematic side view of a thermoelectric device according to some embodiments comprising a plurality of series-connected thermoelectric couples;

FIG. 4 is a schematic illustration of a thermoelectric system according to some embodiments;

FIG. 5 is a scanning electron micrograph image of a thermoelectric device according to some embodiments; and

FIG. 6 is a graph of temperature change across the thermoelectric legs of a passively cooled thermoelectric device versus thermoelectric leg thickness.

### DETAILED DESCRIPTION

In some embodiments, flexible thermoelectric generator is provided comprising n-type and p-type legs, where the n-type and p-type legs each comprise two layers of n-type and p-type materials, respectively, that are bonded together by a heat curing epoxy resin. The bonding of the n-type and the p-type layers using a heat curing epoxy resin provides a low electrical resistance and/or high thermal conductivity bond between the layers that is formed without an epoxy and/or solder, which epoxy or solder have been found to increase electrical resistance and/or decrease thermal conductivity. Moreover, the flexible thermoelectric generator, according to some embodiments of the present disclosure, may comprise flexible substrates, such as metal foil substrates, with good coupling, electrical and thermal, to the n-type and p-type legs. The flexible thermoelectric generator may be fabricated by printing first layers of the n-type and p-type materials onto a first flexible substrate, printing second layers of the n-type and p-type materials onto a second flexible substrate and heat curing the first layers and the second layers such that an n-type leg comprises the two layers of n-type material thermally bonded together by a heat curing epoxy resin and a p-type leg comprises the two layers of p-type material thermally bonded together by a heat curing epoxy resin. The flexible thermoelectric generator provides “thick” legs of n-type and p-type materials that are securely/effectively bonded to the flexible substrates.

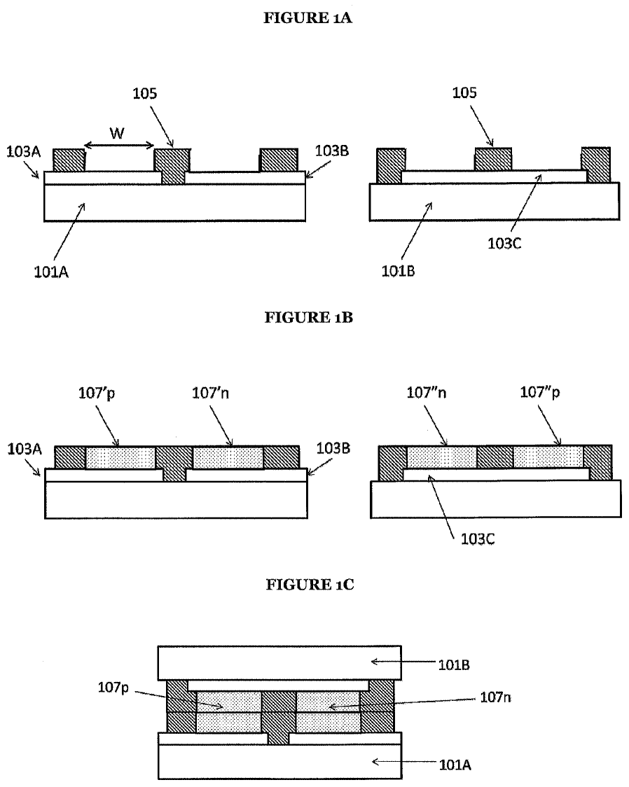

FIG. 1A illustrates a first substrate 101A carrying a first electrical contact 103A and second electrical contact 103B. Each electrical contact described herein comprises one or more conductive layers. Examples of conductive materials for the conductive layer or layers of the electrical contacts include metals, such as copper or gold; metal alloys; conductive metal oxides; and conductive polymers. Optionally, each contact described herein has a thickness between 1 and 5 μm. Each electrical contact described herein may be formed by any suitable technique known to the skilled person, for example sputtering, thermal evaporation or printing, e.g. printing of a metallic paste.

The electrical contacts are partially covered by an insulating structure 105 having apertures formed therein to expose the underlying electrical contacts 103A, 103B. Each aperture defines the perimeter of a well. The well may have a width W and a length in the range of about 0.5-4 mm. The well may have a depth of about 50-250 microns. The electrical contacts 103A, 103B each form a base of a well.

The insulating structure may be a single insulating layer having apertures or a plurality of insulating layers having well-defining apertures formed therein.

The insulating structure may be formed by any known method. In some embodiments, the insulating layer is a positive or negative photoresist. Apertures in the insulating structure may be formed by known photopatterning and etching techniques.

A second substrate 101B carries a third electrical contact 103C and an insulating structure 105. The material or materials of the insulating structure of the second substrate may be the same as or different from that of the first substrate.

The first and second substrates 101A, 101B may each independently be flexible or rigid. In some embodiments, both the first and second substrates are flexible.

In some embodiments, the first and second substrates 101A, 101B may each independently comprise flexible ceramic, plastic film, metal foil or the like. The first and second substrates 101A, 101B may each independently consist of a single layer or may comprise a plurality of layers, for example a metal foil coated on one surface with an electrically-insulating layer, e.g. a polymer layer. The electrically-insulating layer may be thinner than the metal foil. In some embodiments, the electrical contacts may be disposed directly on the electrically insulating layer.

In some embodiments, the substrates 101A, 101B may each independently have a thickness between 30 and 60 μm. The first and second substrates 101A, 101B may be made of the same material or different materials.

With reference to FIG. 1B, material for forming a first n-type thermoelectric leg 107′n is deposited in a well onto the first electrical contact 103A; material for forming a first p-type thermoelectric leg 107′p is deposited in a well onto the second electrical contact 103B; and material for forming second n-type and p-type thermoelectric legs 107″n and 107″p are deposited into wells on third electrical contact 103C. In some embodiments, each thermoelectric leg is in direct contact with the electrical contact. In some embodiments (not shown), one or more intermediate conductive layers may be between a thermoelectric leg and its associated electrical contact.

The p-type semiconductor and the n-type semiconductor of, respectively, the p-type thermoelectric legs and the n-type thermoelectric legs may be selected from known thermoelectric materials as disclosed in, for example, J. Mater. Chem. C, 2015, 3, 10362 and Chem. Soc. Rev., 2016, 45, 6147-6164, the contents of which are incorporated herein by reference.

In some embodiments, at least one of the n-type semiconductor and the p-type semiconductor is in particulate form. The semiconductor particles may be dispersed in an organic or inorganic binder, optionally a polymeric binder. In some embodiments, the binder may comprise or consist of a thermoplastic polymer. In some embodiments, the binder may comprise or consist of a thermosetting polymer. In some embodiments, the binder may comprise or consist of a curable epoxy resin.

The semiconductor particle: binder weight ratio is optionally in the range of about 50:50 to 90:10.

In some embodiments, each n-type thermoelectric leg may comprise an alloy of bismuth, and tellurium or selenium. In some embodiments, the semiconducting material of each n-type thermoelectric leg may comprise or consist of an alloy of bismuth (Bi), and tellurium (Te) or selenium (Se), for example, Bi₂Te₃, and Bi₂Se₃, and/or optionally an n-type dopant. Examples of n-type dopants include selenium (Se), bismuth (Bi), sulfur (S), iodine (I) and/or the like. In some embodiments, the concentration of the n-type dopant may be between 1 and 10 weight %.

In some embodiments, the p-type thermoelectric element may comprise an alloy of bismuth, tellurium and antimony. In some embodiments, the semiconducting material of each p-type thermoelectric leg may comprise or consist of an alloy of bismuth (Bi), tellurium (Te), and antimony (Sb), for example Bi_{1.5}Sb_{0.5}Te₃, and optionally a p-type dopant. In some embodiments, the second semiconducting particles may comprise or consist of an alloy of lead (Pb) and tellurium (Te), an alloy of tin (Sn) and selenium (Se), or an alloy of silicon (Si) and germanium (Ge), and optionally a p-type dopant. Examples of p-type dopants include tellurium (Te), selenium (Se), sulfur (S), arsenic (As), antimony (Sb), phosphorus (P), bismuth (Bi) and the halogens. The concentration of the p-type dopant may be between 1 and 10 weight %.

The material composition of the n-type thermoelectric legs of the first and second substrates may be the same or different.

The material composition of the p-type thermoelectric legs of the first and second substrates may be the same or different.

Suitable techniques for depositing an ink are coating or printing methods include, without limitation, roll-coating, spray coating, doctor blade coating, slit coating, ink jet printing, screen printing, dispense printing, gravure printing, stencil printing and flexographic printing. Dispense printing is particularly preferred. In dispense printing, each thermoelectric leg is formed by depositing a continuous flow of ink from a nozzle positioned above the first electrode. It will be understood that no ink is dispensed in regions between each thermoelectric leg.

An ink as described herein may contain one or more solvents. In some embodiments, the ink comprises two or more solvents. Exemplary solvents include, without limitation, benzene substituted with one or more C₁₋₁₀ alkyl or alkoxy groups, e.g. anisole; ketones, e.g. methyl isobutyl ketone; (MIBK) and carboxylic acid esters e.g. propylene glycol methyl ether acetate (PGMEA).

The components of the ink may be dissolved or suspended in the solvent or solvents of the ink. In some embodiments, the ink comprises a dissolved binder.

With reference to FIG. 1C, the first and second substrates are brought together such that upper surfaces of the first and second n-type thermoelectric legs and upper surfaces of the first and second p-type thermoelectric legs of the first and second substrates come into direct contact. Each first and second thermoelectric legs which are brought in contact with one another form a single, longer, thermoelectric leg.

In some embodiments, alignment marks or alignment structures may be provided on the first and/or second substrate.

In some embodiments, n-type semiconductor of the first n-type thermoelectric leg 107′n comes into direct contact with n-type semiconductor of the second n-type thermoelectric leg 107″n when the first and second substrates are brought together.

In some embodiments, p-type semiconductor of the first p-type thermoelectric leg 107′p comes into direct contact with p-type semiconductor of the second p-type thermoelectric leg 107″p when the first and second substrates are brought together.

The thickness of thermoelectric legs 107p and 107n may be in the range of about 100 microns—1 mm, optionally 200-550 microns.

The first and second thermoelectric legs may be heated when brought into contact, for example by applying heat to an outer surface of one or both of the first and second substrates. If the first and second thermoelectric legs comprise a polymer binder then heat treatment may be at a temperature above the glass transition temperature of the polymer. If the first and second thermoelectric legs comprise a thermosetting polymer, for example an epoxy resin, then curing may result in binding between polymer in the first and second legs.

In some embodiments, heating is at a temperature of about 150° to 250°. In some embodiments, heating is for a time period of about 1 to 3 hours.

The first and second substrates may be pressed together using any suitable apparatus, for example by use of a jig.

An adhesive may be applied between the first and second substrates and extending around a perimeter of the device.

FIGS. 1A-1C illustrate thermoelectric legs having an upper surface which is the same distance from an upper surface of the substrate as the insulating structure.

In some embodiments, at least part of an upper surface of a n-type or a p-type thermoelectric leg of the first and/or second substrate is further from, optionally 10-50 microns from, an upper surface of the substrate than an upper surface of the insulating structure.

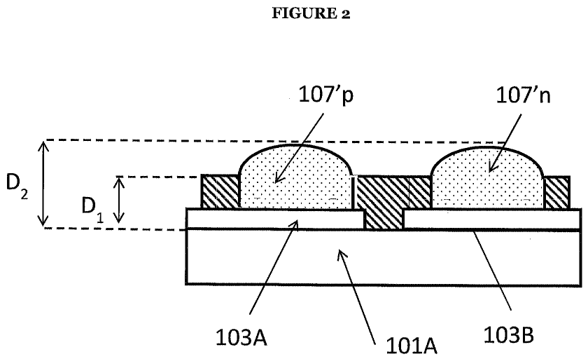

For example, and with reference to FIG. 2, thermoelectric legs 107p′, 107n′ disposed in wells defined in the insulating structure 105 may have a domed upper surface, such that that least part of the upper surface is a distance D₂, which is a distance from the surface of the substrate that the thermoelectric leg is disposed over to a point on the upper surface of the thermoelectric leg, is greater than a distance D₁ which is a distance from the surface of the substrate to an upper surface of the insulating layer.

A domed upper surface may be formed by overfilling of a well-defined by the insulating structure, i.e. by depositing a volume of ink into the well which is greater than a volume of the well. A high contact angle of the ink at the upper surface of the insulating structure may prevent ink in an overfilled well from spreading across the upper surface of the insulating structure.

FIG. 2 illustrates a first substrate carrying thermoelectric legs having a domed upper surface. Thermoelectric legs disposed over the second substrate described herein may, additionally or alternatively, have a domed upper surface.

FIGS. 1A-1C illustrate first and second substrates each carrying an insulating structure defining wells on the surface thereof. In other embodiments, thermoelectric legs may be formed on a substrate which does not carry an insulating structure, for example by depositing an ink onto an electrical contact which has been treated to have high and low surface energy areas or by evaporation of the thermoelectric legs through a mask.

FIG. 1C illustrates a single thermoelectric couple of a thermoelectric device.

Thermoelectric devices as described herein may contain only one thermoelectric couple, or may contain two or more electrically connected thermoelectric couples.

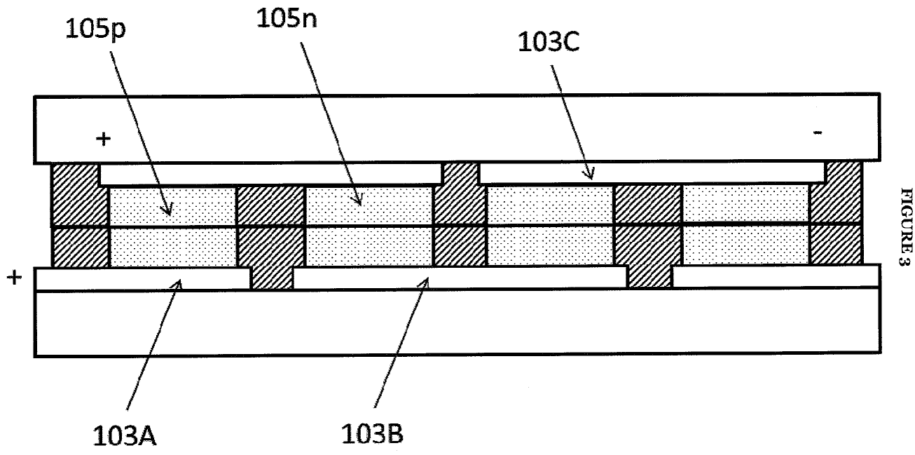

FIG. 3 illustrates a thermoelectric device comprising two thermoelectric couples connected in series, wherein an electrical contact on the first substrate extends between adjacent thermoelectric couples. It will be appreciated that electrical contacts 103A, 103B on the first substrate may be common to adjacent thermoelectric couples. A plurality of thermoelectric couples may be linked, e.g. linked in series, to form an array.

In some embodiments of the present disclosure, whilst pressure is applied, the untreated device is heated (“cured”), for example by an oven or hot plate (step S7). In some embodiments, the untreated device may be heated at between about 150° and 250° for between about 1 and 3 hours.

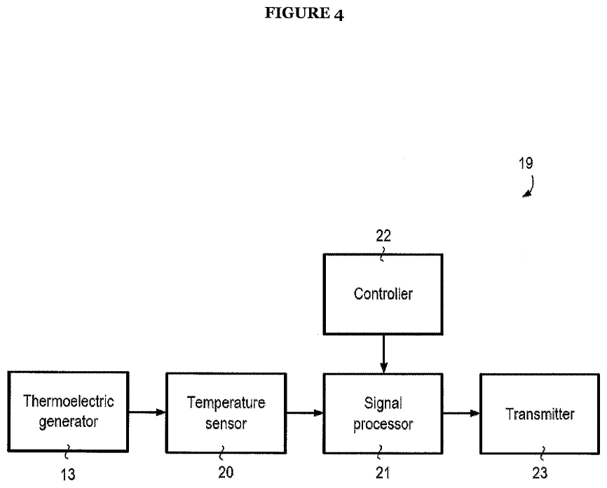

Referring to FIG. 4, an example thermoelectric system (“the system”) 19 comprising a thermoelectric device as described herein is shown. The system 19 may be used to measure a surface temperature of a remote component (not shown) and transmit temperature data to a remote receiver (not shown).

When a given temperature difference δT is applied across the layers of the thermoelectric generator, a voltage is induced across the thermoelectric legs. This voltage drives a current through the contacts and thermoelectric legs.

The system 19 comprises the thermoelectric device 13, a temperature sensor 20, a signal processor unit 21, a controller unit 22, and a transmitter unit 23. The thermoelectric device 13 is provided on a surface of the remote component. The component may be a pipe or a moving mechanical element, for example an actuator. The flexible thermoelectric device 13 may be flexible to maintain surface contact with the remote component to reduce thermal resistance at the contact surface.

The thermoelectric device 13 converts the waste heat produced by the component into useful energy to power the temperature sensor. The signal processor 21 receives at least one signal from the temperature sensor 20. The signal indicates the temperature of the component.

In response to receiving control signals from the controller 22, the signal processor 21 processes the signal. The transmitter 23 receives the processed signal and transmits the processed signal to the external receiver (not shown).

### EXAMPLES

### Device Example 1

First and second substrates of a metal foil with a low thermal resistance insulating layer were provided. Electrical contacts were formed on the insulating layer of the first and second substrates in a complementary fashion so as to provide interconnected thermoelectric couples upon combination of the first and second substrates.

A bank structure was formed over the contacts of each substrate with a photoresist which was patterned by photolithography to form wells exposing the underlying contacts. Each well had a length and width of 2 mm and a depth of 60 microns.

A mechanically alloyed powder of bismuth telluride (n-type) or bismuth antinomy telluride (p-type), was formulated with a heat curing epoxy resin to form n-type and p-type inks in a semiconductor particle : epoxy resin weight ratio of 82:18. A blend of solvents of MIBK: Anisole (7:3 w/w) made up 18 weight % of the inks. The inks were deposited by dispense printing into the wells of the first and second substrates, with the n-type and p-type inks being deposited in alternate wells. Solvent was removed by heating to yield a substantially dry film.

The first and second substrates were aligned and brought into intimate contact, by applying an even sustained pressure across the device with a clamping jig. The assembled device sealed within the jig was heated in an oven between 180° C. and 250° C. (i.e. in a curing temperature range of the epoxy).

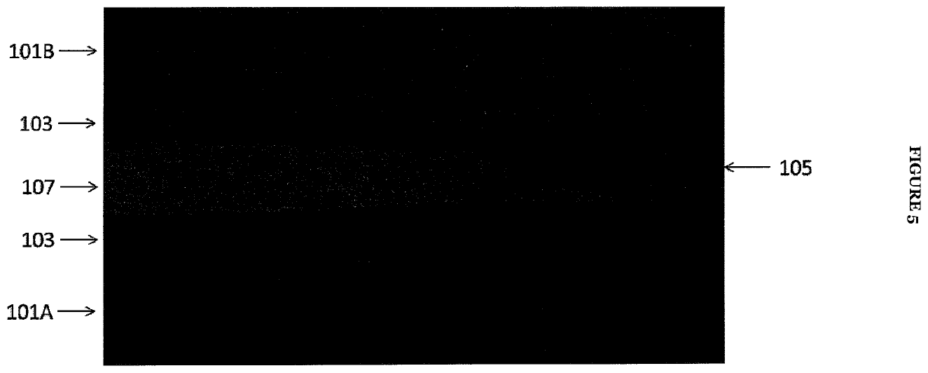

FIG. 5 is a scanning electron micrograph image of a cross-section of the resulting device. The thermoelectric leg 107 formed by combination of a first and second thermoelectric leg of the first and second substrates respectively appears as a smooth, continuous film with no visible join or seam.

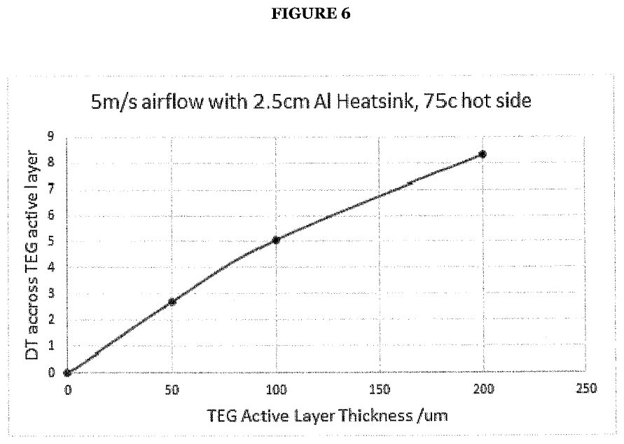

Thermoelectric devices having 50, 100 and 200 micron thick thermoelectric legs were provided between a surface at 75° C. and an aluminium heat sink in an airflow of 5 m/s. Referring to FIG. 6, a greater temperature change is achieved for thicker thermoelectric legs.

The description above provides preferred exemplary embodiment(s) only, and is not intended to limit the scope, applicability or configuration of the invention. Rather, the ensuing description of the preferred exemplary embodiment(s) will provide those skilled in the art with an enabling description for implementing a preferred exemplary embodiment of the invention, it being understood that various changes may be made in the function and arrangement of elements, including combinations of features from different embodiments, without departing from the scope of the invention.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the description above, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

1. A method for producing a thermoelectric device comprising:
providing a first substrate supporting a first n-type thermoelectric leg in electrical communication with a first electrical contact and a first p-type thermoelectric leg in electrical communication with a second electrical contact;
providing a second substrate supporting a second n-type thermoelectric leg and a second p-type thermoelectric leg in electrical communication with a third electrical contact, the third electrical contact extending between the second n-type thermoelectric leg and the second p-type thermoelectric leg; and
forming a thermoelectric couple by bringing the first n-type thermoelectric leg and first p-type thermoelectric leg into direct contact with, respectively, the second n-type thermoelectric leg and the second p-type thermoelectric leg
wherein the n-type thermoelectric leg comprises n-type semiconducting particles dispersed in a first binder or the p-type thermoelectric leg comprises p-type semiconducting particles dispersed in a second binder.

2. A method according to claim 1 wherein the n-type thermoelectric leg comprises n-type semiconducting particles dispersed in a first binder.

3. A method according to claim 2 wherein the n-type semiconducting particles comprise an alloy of bismuth, and tellurium or selenium.

4. A method according to claim 1 wherein the p-type thermoelectric leg comprises p-type semiconducting particles dispersed in a second binder.

5. A method according to claim 4 wherein the p-type semiconducting particles comprise an alloy of bismuth, tellurium and antimony.

6. A method according to claim 2 wherein the first or second binder is a thermosetting polymer.

7. A method according to claim 2 wherein the first or second binder is a heat-curable epoxy.

8. A method according to claim 1 wherein heat is applied to the thermoelectric legs upon contact of the first and second n-type thermoelectric legs and the first and second p-type thermoelectric legs.

9. A method according to claim 1 wherein at least one of the first p-type thermoelectric leg, the first n-type thermoelectric leg, the second p-type thermoelectric leg and the second n-type thermoelectric leg is formed by printing an ink onto the electrical contact associated with the thermoelectric leg.

10. A method according to claim 9 wherein a first patterned insulating structure comprising apertures exposing the first and second electrical contacts is supported by the first substrate and wherein the ink is printed into the apertures.

11. A method according to claim 9 wherein a second patterned insulating structure comprising apertures exposing the third electrical contact is supported by the second substrate and wherein the ink is printed into the apertures.

12. A method according to claim 1 wherein an adhesive is applied to a perimeter of the device between the first and second electrodes in between the first and second substrates.

13. A method according to claim 1 wherein the thermoelectric device is flexible.

14. A method according to claim 13 wherein at least one of the first and second substrates comprises a metal foil layer and an insulating layer.

15. A method according to claim 1 wherein the thermoelectric device comprises a plurality of electrically connected thermoelectric couples, the plurality of electrically connected thermoelectric couples being formed by bringing a plurality of the first n-type thermoelectric legs and a plurality of the first p-type thermoelectric legs into direct contact with, respectively, a plurality of the second n-type thermoelectric legs and a plurality of the second p-type thermoelectric legs.

16-23. (canceled)

24. The method according to claim 1 wherein wherein the n-type thermoelectric leg comprises n-type semiconducting particles dispersed in a first binder and the p-type thermoelectric leg comprises p-type semiconducting particles dispersed in a second binder.
